(19) United States
(12) Patent Application Publication
(10) Pub. No.: US 2016/0105949 A1
(43) Pub. Date: Apr. 14, 2016

(54) PRINTED CIRCUIT BOARD AND DISPLAY DEVICE

(71) Applicant: Shenzhen China Star Optoelectronics Technology Co. LTD., Shenzhen, Guangdong (CN)

(72) Inventor: Jianyong Fu, Guangdong (CN)

(21) Appl. No.: 14/408,602

(22) PCT Filed: Oct. 20, 2014
(86) PCT No.: PCT/CN2014/088892

§ 371 Date: Dec. 17, 2014

(30) Foreign Application Priority Data
Oct. 14, 2014 (CN) 201410541359.X

(51) Int. Cl. H05K 1/02; H05K 1/18

(52) U.S. Cl. CPC H05K 1/0206; H05K 1/181

(57) ABSTRACT

A printed circuit board and a display device are provided. The printed circuit board comprises a substrate, a package chip, and a metal heat dissipation layer. The package chip is disposed on a first surface of the substrate and comprises a chip body. The metal heat dissipation layer is disposed on a second surface of the substrate. A projection of the metal heat dissipation layer on the first surface of the substrate covers the chip body. The metal heat dissipation layer of the present invention is disposed on the reverse side of the printed circuit board to reduce the temperature of the package chip.

### FIELD OF THE INVENTION

The present invention relates to a technical field of manufacturing a printed circuit board, and in particular to a printed circuit board and a display device.

### BACKGROUND OF THE INVENTION

The printed circuit board is a supporter of an electronic component, and a carrier connected to electronic components. The quality of a product is affected directly by the design of the printed circuit board and the quality of its manufacture.

A chip is connected to the printed circuit board. When the temperature of the chip approaches 150 degrees Celsius, the chip will be turned off. The data of the chip thus cannot be restored, and the product will be lost. Therefore, the temperature of the chip must be reduced to avoid the chip from being turned off.

Recently, the circuit components around the chip are dispersed in the layout of the printed circuit board to reduce the temperature of the chip. However, the temperature of the chip can be reduced a little when the temperature is too high. Thus the problems arising from being overheated cannot be solved.

Therefore, a printed circuit board and a display device are desired to be developed, so as solve the problems existing in the conventional as described above.

### SUMMARY OF THE INVENTION

A primary object of the present invention is to provide a printed circuit board and a display device, which reduces the temperature of the package chip.

To achieve the above object, the present invention provides a printed circuit board which comprises a substrate, a package chip, and a metal heat dissipation layer. The substrate comprises a first surface and a second surface opposite the first surface. The package chip is disposed on the first surface of the substrate and comprises a chip body and a plurality of pins. The metal heat dissipation layer is disposed on the second surface, wherein a projection of the metal heat dissipation layer on the first surface of the substrate covers the chip body, and an area of the metal heat dissipation layer is greater than or equal to an area of the chip body, and a plurality of through holes are disposed on the substrate corresponding to the metal heat dissipation layer.

In the printed circuit board of the present invention, each of the through holes has an extending direction, and the extending direction is perpendicular to the first surface of the substrate.

In the printed circuit board of the present invention, each of the through holes has a cross section, and the cross section is circular and parallel to the first surface of the substrate.

In the printed circuit board of the present invention, a diameter of the through hole is in a range of 0.5 millimeters to 0.6 millimeters.

In the printed circuit board of the present invention, a distance between each two adjacent through holes is in a range of 0.5 millimeters to 2 millimeters.

In the printed circuit board of the present invention, a metal layer is disposed on an inner wall of the through hole, and a diameter of the through hole is in a range of 0.25 millimeters to 0.3 millimeters.

In the printed circuit board of the present invention, the area of the metal heat dissipation layer is 1 to 2 times the area of the chip body.

To achieve the above object, the present invention provides a printed circuit board which comprises a substrate, a package chip, and a metal heat dissipation layer. The substrate comprises a first surface and a second surface opposite the first surface. The package chip is disposed on the first surface of the substrate and comprises a chip body and a plurality of pins. The metal heat dissipation layer is disposed on the second surface, wherein a projection of the metal heat dissipation layer on the first surface of the substrate covers the chip body.

In the printed circuit board of the present invention, a plurality of through holes are disposed on the substrate corresponding to the metal heat dissipation layer.

In the printed circuit board of the present invention, each of the through holes has an extending direction, and the extending direction is perpendicular to the first surface of the substrate.

In the printed circuit board of the present invention, each of the through holes has a cross section, and the cross section is round and parallel to the first surface of the substrate.

In the printed circuit board of the present invention, a diameter of the through hole is 0.5 millimeters to 0.6 millimeters.

In the printed circuit board of the present invention, a distance between each two adjacent through holes is 0.5 millimeters to 2 millimeters.

In the printed circuit board of the present invention, a metal layer is disposed on an inner wall of the through hole, and a diameter of the through hole is 0.25 millimeters to 0.3 millimeters.

In the printed circuit board of the present invention, an area of the metal heat dissipation layer is greater than or equal to an area of the chip body.

In the printed circuit board of the present invention, the area of the metal heat dissipation layer is 1 to 2 times greater than the area of the chip body.

To achieve the above object, the present invention provides a display device which comprises at least one printed circuit board, wherein the printed circuit board comprises a substrate, a package chip, and a metal heat dissipation layer. The substrate comprises a first surface and a second surface opposite the first surface. The package chip is disposed on the first surface of the substrate and comprises a chip body and a plurality of pins. The metal heat dissipation layer is disposed on the second surface, wherein a projection of the metal heat dissipation layer on the first surface of the substrate covers the chip body.

In the display device of the present invention, a plurality of through holes are disposed on the substrate corresponding to the metal heat dissipation layer.

In the display device of the present invention, each of the through holes has an extending direction, and the extending direction is perpendicular to the first surface of the substrate.

In the display device of the present invention, each of the through holes has a cross section, and the cross section is round and parallel to the first surface of the substrate.

In the printed circuit board and the display device of the present invention, the metal heat dissipation layer is disposed on the inverse of the printed circuit board to reduce the temperature of the package chip, and to solve the problems existing in the conventional printed circuit board.

### DESCRIPTION OF THE DRAWINGS

FIG. 1 is a schematic view of a face of a printed circuit board according to an embodiment of the present invention; and

FIG. 2 is a schematic view of a reverse side of a printed circuit board according to an embodiment of the present invention.

### DETAILED DESCRIPTION OF THE PREFERRED EMBODIMENTS

The structure and the technical means adopted by the present invention to achieve the above and other objects can be best understood by referring to the following detailed description of the preferred embodiments and the accompanying drawings. Furthermore, directional terms described by the present invention, such as upper, lower, front, back, left, right, inner, outer, side, longitudinal/vertical, transverse/horizontal, etc., are only directions by referring to the accompanying drawings, and thus the used directional terms are used to describe and understand the present invention, but the present invention is not limited thereto.

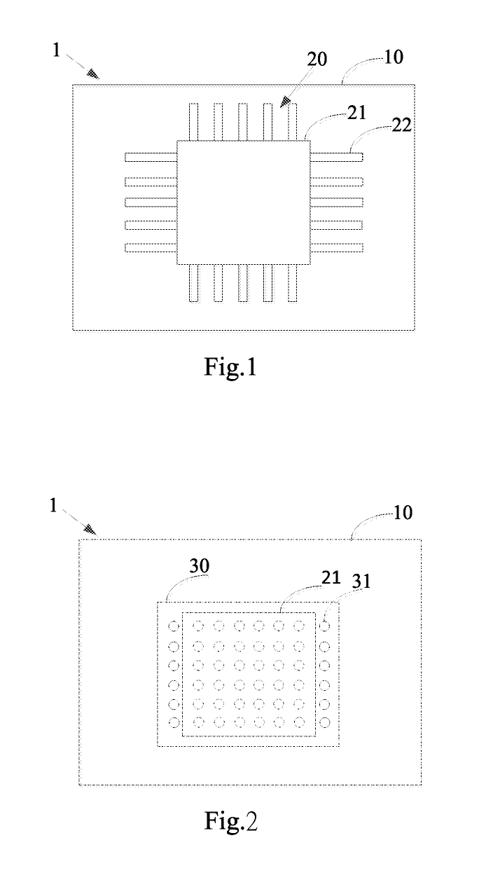

FIG. 1 shows a schematic view of a face of a printed circuit board according to an embodiment of the present invention.

The printed circuit board 1 of the present invention comprises a substrate 10 connected to electronic components. The substrate 10 may be a signal layer, double layers, or multilayer. Referring to FIG. 1, the substrate 10 comprises a first surface and a second surface opposite the first surface. The electronic components (such as a package chip 20) are disposed on the first surface (face) of the substrate 10. The package chip 20 comprises a chip body 21 and a plurality of pins 22. For example, the package chip 20 is a pulse width modulation chip. FIG. 2 shows a schematic view of a reverse side of a printed circuit board according to an embodiment of the present invention. Referring to FIG. 2, a metal heat dissipation layer 30 is disposed on the second surface (the reverse side); a projection of the chip body 21 on the second surface of the substrate 10 is also shown in FIG. 2. The metal heat dissipation layer 30 is preferably copper or other metals. A projection of the metal heat dissipation layer 30 on the first surface of the substrate 30 covers the chip body 21. FIG. 2 shows that an area of the metal heat dissipation layer 30 is greater than the projection of the chip body 21 on the second surface of the substrate 10.

A plurality of through holes 31 are disposed on the substrate 10 corresponding to the metal heat dissipation layer 30. The through holes 31 are drilled along an extending direction, and the extending direction is perpendicular to the first surface of the substrate 10. The through holes 31 are also drilled along a slanted direction or other directions to implement the heat dissipation. A cross section of the through hole is circular or polygonal, and parallel to the first surface of the substrate 10. If the cross section of the through hole is circular, then the diameter of the through hole is in a range of 0.5 millimeters to 0.6 millimeters, such as 0.52 millimeters, 0.53 millimeters, 0.54 millimeters, 0.55 millimeters, 0.56 millimeters, 0.57 millimeters, or 0.58 millimeters. If the diameter of the through hole is in the said range, then heat dissipation can be ensured, and tin leaking can be avoided while the chip body 21 is connected to the substrate 10.

An interval is preferably provided between each two adjacent through holes 31, and a distance between each two adjacent through holes is in a range of 0.5 millimeters to 2 millimeters, such as 0.6 millimeters, 0.7 millimeters, 0.8 millimeters, 0.9 millimeters, 1 millimeters, 1.2 millimeters, 1.4 millimeters, 1.5 millimeters, 1.7 millimeters, or 1.9 millimeters. If the distance is too long, heat dissipation is poor. If the distance is too short, the printed circuit board 1 will be injured by drilling the through holes 31. A plurality of notches are also disposed on a edge of the through holes 31 to increase the area of the heat dissipation. A plurality of bumps are also disposed on a edge of the through holes 31, and made of metal to dissipate heat.

A metal layer is also disposed on an inner wall of the through holes 31 to provide a welding point of the chip body 21, so that the connection between the chip body 21 and the substrate 10 can be ensured. The metal layer and the metal heat dissipation layer 30 are preferably copper or other metals. Preferably, a ring of the metal layer is a circular. Preferably, an inner diameter of the through hole is in a range of 0.25 millimeters to 0.3 millimeters, such as 0.26 millimeters, 0.27 millimeters, 0.28 millimeters, or 0.29 millimeters; an outer diameter of the through hole is in a range of 0.5 millimeters to 0.6 millimeters, such as 0.52 millimeters, 0.53 millimeters, 0.54 millimeters, 0.55 millimeters, 0.56 millimeters, 0.57 millimeters, or 0.58 millimeters. If the diameter of the through hole is in the said range, then the heat dissipation can be ensured, and tin leaking can be avoided while the chip body 21 is connected to the substrate 10.

Preferably, an area of the metal heat dissipation layer 30 is greater than or equal to an area of the chip body 21, and the area of the metal heat dissipation layer 30 is 1 to 2 times the area of the chip body 21, such as 1.2 times, 1.3 times, 1.4 times, 1.5 times, 1.6 times, 1.7 times, 1.8 times, or 1.9 times. If the area of the metal heat dissipation layer 30 and the chip body 21 are in the said range, the heat dissipation of the package chip can be ensured.

In the printed circuit board of the present invention, the metal heat dissipation layer is disposed on the reverse side of the printed circuit board to reduce the temperature of the package chip, and to solve the problems existing in the conventional printed circuit board.

As shown in to FIG. 1, the present invention provides a display device which comprises at least one printed circuit board 1, wherein the printed circuit board 1 comprises a substrate 10 connected to electronic components. The substrate 10 is a signal layer, double layers, or multilayer. Referring to FIG. 1, the substrate 10 comprises a first surface and a second surface opposite the first surface. The electronic components and a package chip 20, are disposed on the first surface (face) of the substrate 10. The package chip 20 comprises a chip body 21 and a plurality of pins 22. For example, the package chip 20 is a pulse width modulation chip. FIG. 2 shows a schematic view of a reverse side of a printed circuit board according to an embodiment of the present invention. Referring to FIG. 2, a metal heat dissipation layer 30 is disposed on the second surface (the a reverse side), a projection of the chip body 21 on the second surface of the substrate 10 is shown in FIG. 2. The metal heat dissipation layer 30 is preferably copper or other metals. A projection of the metal heat dissipation layer 30 on the first surface of the substrate 30 covers the chip body 21. FIG. 2 shows that an area of the metal heat dissipation layer 30 is greater than the projection of the chip body 21 on the second surface of the substrate 10.

A plurality of through holes 31 are disposed on the substrate 10 corresponding to the metal heat dissipation layer 30. The through holes 31 are drilled along an extending direction, and the extending direction is perpendicular to the first surface of the substrate 10. The through holes 31 are also drilled along a slanted direction or other directions to implement heat dissipation. A cross section of the through hole is circular or polygonal, and parallel to the first surface of the substrate 10. If the cross section of the through hole is circular, then the diameter of the through hole is in a range of 0.5 millimeters to 0.6 millimeters, such as 0.52 millimeters, 0.53 millimeters, 0.54 millimeters, 0.55 millimeters, 0.56 millimeters, 0.57 millimeters, or 0.58 millimeters. If the diameter of the through hole is in the said range, then heat dissipation can be ensured, and tin leaking can be avoided while the chip body 21 is connected to the substrate 10.

Preferably, an interval is preferably provided between each two adjacent through holes 31, and a distance between each two adjacent through holes is in a range of 0.5 millimeters to 2 millimeters, such as 0.6 millimeters, 0.7 millimeters, 0.8 millimeters, 0.9 millimeters, 1 millimeters, 1.2 millimeters, 1.4 millimeters, 1.5 millimeters, 1.7 millimeters, or 1.9 millimeters. If the distance is too long, heat dissipation is poor. If the distance is too short, the printed circuit board 1 will be injured by drilling the through holes 31. A plurality of notches are also disposed on an edge of the through holes 31 to increase the area of the heat dissipation. A plurality of bumps are also disposed on an edge of the through holes 31, and made of metal to dissipate the heat.

A metal layer is also disposed on an inner wall of the through holes 31 to provide a welding point of the chip body 21, so that the connection between the chip body 21 and the substrate 10 can be ensured. The metal layer and the metal heat dissipation layer 30 are preferably copper or other metals. Preferably, a ring of the metal layer is a circular. Preferably, an inner diameter of the through hole is in a range of 0.25 millimeters to 0.3 millimeters, such as 0.26 millimeters, 0.27 millimeters, 0.28 millimeters, or 0.29 millimeters; an outer diameter of the through hole is in a range of 0.5 millimeters to 0.6 millimeters, such as 0.52 millimeters, 0.53 millimeters, 0.54 millimeters, 0.55 millimeters, 0.56 millimeters, 0.57 millimeters, or 0.58 millimeters. If the diameter of the through hole is in the said range, then the heat dissipation can be ensured, and tin leaking can be avoided while the chip body 21 is connected to the substrate 10.

Preferably, an area of the metal heat dissipation layer 30 is greater than or equal to an area of the chip body 21, and the area of the metal heat dissipation layer 30 is 1 to 2 times the area of the chip body 21, such as 1.2 times, 1.3 times, 1.4 times, 1.5 times, 1.6 times, 1.7 times, 1.8 times, or 1.9 times. If the area of the metal heat dissipation layer 30 and the chip body 21 are in the said range, the heat dissipation of the package chip can be ensured.

In the display device of the present invention, the metal heat dissipation layer is disposed on the reverse side of the printed circuit board to reduce the temperature of the package chip, and to solve the problems existing in the conventional printed circuit board.

As above, the present invention has been described with a preferred embodiment thereof and it is understood that many changes and modifications to the described embodiment can be carried out without departing from the scope and the spirit of the invention that is intended to be limited only by the appended claims.

What is claimed is:

1. A printed circuit board, comprising:
a substrate comprising a first surface and a second surface opposite the first surface;
a package chip disposed on the first surface of the substrate and comprising a chip body and a plurality of pins; and
a metal heat dissipation layer disposed on the second surface;
wherein a projection of the metal heat dissipation layer on the first surface of the substrate covers the chip body, and an area of the metal heat dissipation layer is greater than or equal to an area of the chip body, and a plurality of through holes are disposed on the substrate corresponding to the metal heat dissipation layer.

2. The printed circuit board according to claim 1, wherein each of the through holes has an extending direction, and the extending direction is perpendicular to the first surface of the substrate.

3. The printed circuit board according to claim 1, wherein each of the through holes has a cross section, and the cross section is circular and parallel to the first surface of the substrate.

4. The printed circuit board according to claim 3, wherein a diameter of the through hole is in a range of 0.5 millimeters to 0.6 millimeters.

5. The printed circuit board according to claim 1, wherein a distance between each two adjacent through holes is in a range of 0.5 millimeters to 2 millimeters.

6. The printed circuit board according to claim 1, wherein a metal layer is disposed on an inner wall of the through hole, and a diameter of the through hole is in a range of 0.25 millimeters to 0.3 millimeters.

7. The printed circuit board according to claim 1, wherein the area of the metal heat dissipation layer is 1 to 2 times the area of the chip body.

8. A printed circuit board, comprising:
a substrate comprising a first surface and a second surface opposite the first surface;
a package chip disposed on the first surface of the substrate and comprising a chip body and a plurality of pins; and
a metal heat dissipation layer disposed on the second surface;
wherein a projection of the metal heat dissipation layer on the first surface of the substrate covers the chip body.

9. The printed circuit board according to claim 8, wherein a plurality of through holes are disposed on the substrate corresponding to the metal heat dissipation layer.

10. The printed circuit board according to claim 9, wherein each of the through holes has an extending direction, and the extending direction is perpendicular to the first surface of the substrate.

11. The printed circuit board according to claim 9, wherein each of the through holes has a cross section, and the cross section is circular and parallel to the first surface of the substrate.

12. The printed circuit board according to claim 11, wherein a diameter of the through hole is 0.5 millimeters to 0.6 millimeters.

13. The printed circuit board according to claim 9, wherein a distance between each two adjacent through holes is 0.5 millimeters to 2 millimeters.

14. The printed circuit board according to claim 9, wherein a metal layer is disposed on an inner wall of the through hole, and a diameter of the through hole is 0.25 millimeters to 0.3 millimeters.

15. The printed circuit board according to claim 8, wherein an area of the metal heat dissipation layer is greater than or equal to an area of the chip body.

16. The printed circuit board according to claim 15, wherein the area of the metal heat dissipation layer is 1 to 2 times greater than the area of the chip body.

17. A display device comprising at least one printed circuit board, wherein the printed circuit board comprises:
a substrate comprising a first surface and a second surface opposite the first surface;
a package chip disposed on the first surface of the substrate and comprising a chip body and a plurality of pins; and
a metal heat dissipation layer disposed on the second surface;
wherein a projection of the metal heat dissipation layer on the first surface of the substrate covers the chip body.

18. The display device according to claim 17, wherein a plurality of through holes are disposed on the substrate corresponding to the metal heat dissipation layer.

19. The display device according to claim 18, wherein each of the through holes has an extending direction, and the extending direction is perpendicular to the first surface of the substrate.

20. The display device according to claim 18, wherein each of the through holes has a cross section, and the cross section is circular and parallel to the first surface of the substrate.
